(19) United States
(12) Patent Application Publication
(10) Pub. No.: US 2008/0001650 A1
(43) Pub. Date: Jan. 3, 2008

(54) Controlling output current delivered by a transistor

(75) Inventor: Didier Belot, Rives (FR)

Correspondence Address: DOCKET CLERK, P.O. DRAWER 800889, DALLAS, TX, 75380, US

(73) Assignee: STMicroelectronics SA, Montrouge (FR)

(21) Appl. No.: 11/820,495

(22) Filed: Jun. 19, 2007

(30) Foreign Application Priority Data
Jun. 23, 2006 (FR) 06/05645

(51) Int. Cl. H03K 3/01

(52) U.S. Cl. 327/534

(57) ABSTRACT

The integrated circuit includes at least one transistor (TR) that comprises an output electrode capable of delivering an output current (I_{D}) in response to an input signal received on its control electrode. The transistor is formed inside a biasable semiconductor well of the SOI type. The circuit also comprises control means (INV) capable of receiving a control signal (SC) and capable of adjusting the value of the bias voltage of the well (V_{BS}) as a function of the value of the control signal. The transistor (TR) is then capable of generating the value of the output current (I_{D}) as a function of the value of the bias voltage of the well.

### CROSS-REFERENCE TO RELATED APPLICATIONS

The present application is related to French Patent Application No. 0605645, filed Jun. 23, 2006, entitled “METHOD FOR CONTROLLING AN OUTPUT CURRENT DELIVERED BY A TRANSISTOR AND CORRESPONDING INTEGRATED CIRCUIT”. French Patent Application No. 0605645 is assigned to the assignee of the present application and is hereby incorporated by reference into the present disclosure as if fully set forth herein. The present application hereby claims priority under 35 U.S.C. §119(a) to French Patent Application No. 0605645.

### TECHNICAL FIELD

The present disclosure relates microelectronics and, in particular, to integrated circuits having an amplifier powered by a current controlled by a transistor.

### BACKGROUND

Conventionally, an amplifier could be connected to an output electrode of a transistor (for example, an amplifier could be connected to a drain of the transistor such as n-MOS type transistors). These transistors are typically controlled by a control electrode (i.e., the gate in a MOS type transistor of the MOS type) and by a control voltage.

In order to zero this power supply current and consequently to interrupt the operation of the amplifier, a circuit-cutoff means needs to be provided to connect the gate of the transistor directly to ground. These means for circuit-cutoff, however, completely zero the current and accomplish this in a particularly abrupt manner. Following this current cutoff, the re-establishment of the amplifier operation is then relatively slow.

There is therefore a need for improved systems and methods of controlling the output current delivered by a transistor.

### SUMMARY

Embodiments of the present disclosure provide, for example, systems and methods for controlling an output current delivered by a transistor in response to an input signal received on its control electrode.

In one embodiment, the present disclosure provides a method of controlling an output current of a transistor disposed inside a semiconductor well. The method includes in response to an input signal received on a control electrode of the transistor, adjusting the value of a bias voltage of the semiconductor well.

In another embodiment, the present disclosure provides an integrated circuit. The integrated circuit includes a transistor disposed inside a semiconductor well. The transistor has an output electrode to deliver an output current in response to an input signal received on a control electrode of the transistor. The integrated circuit also includes a control circuit to receive a control signal and to adjust the value of the bias voltage of the semiconductor well as a function of the value of the control signal.

In still another embodiment, the present disclosure provides a receiver for use in a wireless communication system. The receiver includes a transistor disposed inside a semiconductor well. The transistor includes an output electrode to deliver an output current in response to an input signal received on a control electrode of the transistor. The receiver also includes a control circuit to receive a control signal and to adjust the value of the bias voltage of the semiconductor well as a function of the value of the control signal.

Other technical features may be readily apparent to one skilled in the art from the following figures, descriptions and claims.

### BRIEF DESCRIPTION OF THE DRAWINGS

For a more complete understanding of this disclosure and its features, reference is now made to the following description, taken in conjunction with the accompanying drawings, in which:

FIG. 1 shows schematically an exemplary embodiment of a cellular mobile telephone incorporating a low-noise amplifier containing an integrated circuit according to one embodiment of the present disclosure;

FIG. 2 is a somewhat simplified schematic of one embodiment of a circuit according to the present disclosure; and

FIG. 3 is exemplary embodiment of a transistor of an integrated circuit according to the present disclosure.

### DETAILED DESCRIPTION

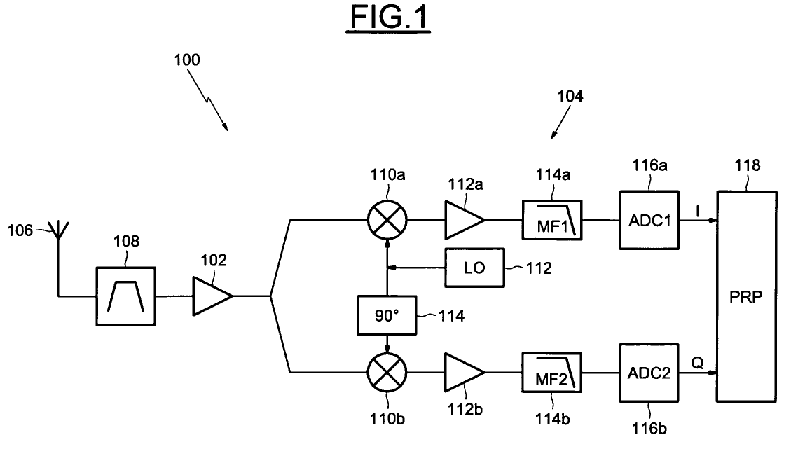

FIG. 1 is a somewhat simplified diagram illustrating an exemplary embodiment of a cellular mobile telephone (TP) 100 incorporating a low-noise amplifier (LNA) 102 and containing an integrated circuit according to one embodiment of the present disclosure. FIG. 1 is for illustration purposes only. Any suitable cellular mobile telephone 100 or other device could be used according to the present disclosure.

In particular, FIG. 1 illustrates the analog part of a receiver system of a cellular mobile telephone (TP) 100. The telephone 100 could include a receiver means (MREC) 104 connected to an antenna (ANT) 106. In this example, the receiver means (MREC) 104 is configured for the reception of the direct conversion type. The antenna (ANT) 106 is connected to a filter (FS) 108 for selection of the reception band, for example, a filter of the SAW (Surface Acoustic Wave) type.

The receiver means (MREC) 104 could, for example, be a tuner device. The tuner device could advantageously be entirely fabricated in an integrated manner on a silicon substrate. It is for example of the zero intermediate frequency type. In other words it does not carry out a frequency transposition to an intermediate frequency, but only comprises a single frequency transposition stage, here comprising the mixers (MEL1) 110a and (MEL2) 110b which perform a direct transposition into baseband.

The receiver means (MREC) 104 includes a variable-gain low-noise amplifier (LNA) 102 connected between the selection filter (FS) 108 and the mixers (MEL1) 110a and (MEL2) 110b. The fabrication of LNA amplifier 102 will be described in more detail later herein. An oscillator (LO) 112 conventionally delivers a transposition signal to the mixer (MEL1) 110a and to the mixer (MEL2) 110b via a 90° phase-shifter (DP) 114.

The processing channel including the mixer (MEL1) 110a is therefore the in-phase channel (I channel), whereas the processing channel containing the mixer (MEL2) 110b is the quadrature channel (Q channel). Each of the mixers 110a and 100b for each channel is followed by a variable-gain amplifier, (VGA1) 112a and (VGA2) 112b, respectively, which are followed by two filtering means (MF1) 114a and (MF2) 114b. Filtering means (MF1) 114a and (MF2) 114b could include low-pass filters respectively connected to the inputs of analog/digital converters (ADC1) 116a and (ADC2) 116b. The analog/digital converters (ADC1) 116a and (ADC2) 116b are connected to a digital processing stage comprising a processor (PRP) 118. Processor (PRP) 118 could be commonly referred to as ‘baseband processor’.

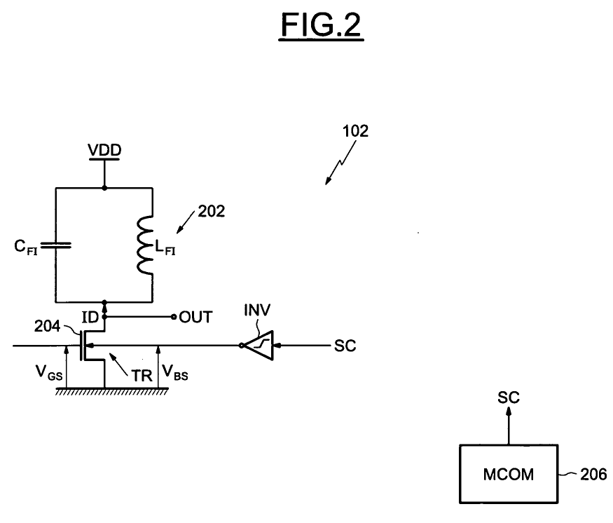

In one embodiment, the low-noise amplifier (LNA) 102 includes, for example, a filter (FI) 202 of the LC type, as illustrated in FIG. 2. The low-noise amplifier (LNA) 102 is for illustration purposes only. Other suitable configurations of low-noise amplifier (LNA) 102 and filter (FI) 202 could also be used according to the present disclosure.

The filter (FI) 202 comprises a capacitor (C_{FI}) coupled in parallel with a coil (L_{FI}) between a power supply terminal delivering the voltage (V_{DD}) and earth, via a transistor (TR) 204. The gate of this transistor (TR) 204 is connected to the aforementioned filter (FS) 108.

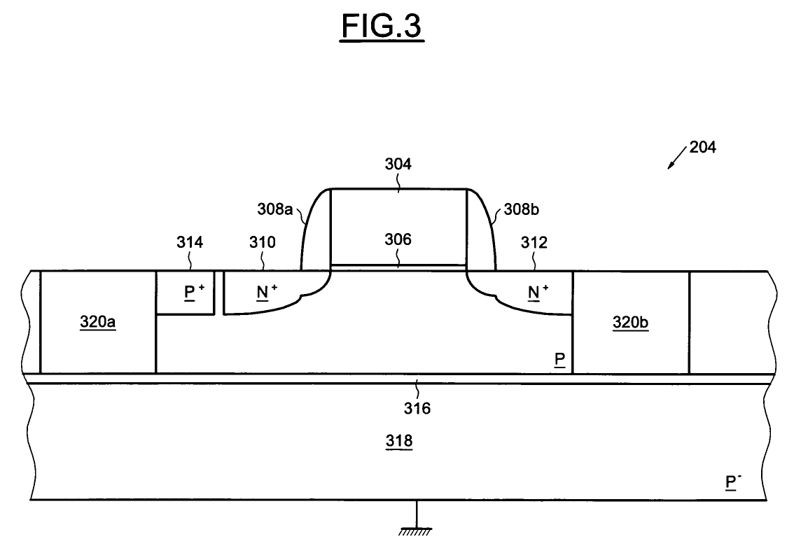

The transistor (TR) 204 shown in FIG. 2 is a transistor formed on a biasable semiconductor well (CSN) 302 of the SOI type as shown in FIG. 3. The transistor (TR) 204 is shown for illustration purposes only. Other suitable transistors could also be used according to the present disclosure. The transistor (TR) 204 in the example shown is a transistor of the n-MOS type.

In one embodiment, transistor (TR) 204 includes a gate (G) 304 formed on the well (CSN) 302 having a p-type conductivity type. An oxide layer (OX) 306 separates the gate (G) 304 from the well (CSN) 302. Two spacers (ESP1) 308a and (ESP2) 308b are formed on either side of the gate (G) 304 on top of the well (CSN) 302. Inside the well (CSN) 302, under the spacers (ESP1) 308a and ESP2 (308b) and extending beyond each spacer, the source (S) 310 and the drain (D) 312 are respectively formed, having an n+ type conductivity.

In one embodiment, a contact region (CT) 314, of the p+ conductivity type, allows the well (CSN) 302 to be biased. The latter is formed on an insulating layer (ISO) 316 (for example SiO₂), itself formed on a semiconductor substrate (SUB) 318 having a p− conductivity type. The substrate (SUB) 318 is connected to earth. Insulating trenches (STI) 320a and 320b are formed on either side of the well (CSN) 302. Thus, insulating trenches (STI) 320a and 320b aid in allowing the well (CSN) 302 to be isolated from the adjacent transistors.

Referring to FIG. 2, the transistor (TR) 204 delivers a power supply current (I_{D}) to the filter (FI) 202, via its drain. When the transistor (TR) 204 is in its linear region of operation, the current (I_{D}) is given by the relationship shown in Equation 1 below.

$${I}_{D} = {\frac{μ n . Cox . W}{2 L} [ {V}_{GS} - {V}_{T} ]}^{2} \qquad ( Eqn . 1 )$$

In Equation 1, W is the width of the gate (G) 304 of the transistor 204, L is the length of the gate (G) 304 of the transistor 204, Cox is the oxide capacitance of the transistor 204, μ is the mobility, V_{GS} is the value of the voltage applied to the gate (G) 304 of the transistor 204, and V_{T} is the threshold voltage of the transistor 204.

The threshold voltage (V_{T}) may be expressed according to the relationship shown in Equation 2 below.

$${V}_{T} = {V}_{T 0} + γ [ \sqrt{( 2 {φ}_{F} - {V}_{BS} )} - \sqrt{2 {φ}_{F}} ] \qquad ( Eqn . 2 )$$

In Equation 2, V_{T0} is the DC component of the value of the threshold voltage, γ is the gate (G) 304 rear coefficient, 2φ_{F} is the hard inversion potential, and V_{BS} is the voltage between the source and the well (CSN) 302 of the transistor 204.

Consequently, by replacing the value of the threshold voltage (V_{T}) in the expression for the drain current (I_{D}) by its expression hereinabove, it can be seen that, by adjusting the voltage between the source (S) 310 and the well (CSN) 302 (V_{BS}), the value of the drain current (I_{D}) can be controlled. In particular, when the value of the voltage (V_{BS}) tends towards (V_{GS}−V_{T0}), the value of the current (I_{D}) tends to zero.

In order to control the value of the voltage (V_{BS}), the low-noise amplifier (LNA) 102 includes a control means. The control means could be formed using a limiting inverter (INV) capable of delivering a voltage limited to a maximum of 2φ_{F}. For example, the value of a diode threshold voltage of around 0.4 Volts will be taken as the limit.

Those skilled in the art will be able to adapt the control means, for example by using another type of logic gate. The inverter (INV) receives at its input a control signal (SC) delivered by control means (MCOM) 206 shown in FIG. 2, for example incorporated within the processor (PRP) 118 shown in FIG. 1. The inverter (INV) delivers the value of the voltage V_{BS} at its output as a function of the value taken by the control signal (SC). An example is given herein below.

If the control signal takes a maximum value, for example 1, the threshold voltage (V_{T}) takes its minimum value, i.e. V_{T0}, and the drain current (I_{D}) takes its maximum value denoted as I_{D0}. On the other hand, if the control signal takes its minimum value, here 0, the voltage delivered by the limiting inverter (INV) is limited to its limit value and the threshold voltage (V_{T}) takes its maximum value V_{Tmax}, whereas the drain current (I_{D}) takes its minimum value, here denoted as I_{Dmin}. Table 1 below summarizes these various possibilities in tabular form.

TABLE 1

SC

| | 1 | 0 |
|---|---|---|
| V_{T} | V_{T0} | V_{Tmax} |
| I_{D} | I_{D0} | I_{Dmin} |

Thus, if the voltage V_{BS} is zero, in other words the threshold voltage (V_{T}) is equal to V_{T0}, the transistor is in its region of normal operation: I_{D} is then equal to I_{D0}. On the other hand, if V_{BS} is at its maximum value, i.e. V_{DD}, the threshold voltage is then at its maximum value, V_{Tmax}, implying that the drain current I_{D} is very low.

The transistor (TR) 204 is therefore almost turned off. However, the existence of a residual current (I_{Dmin}) allows the transistor (TR) 204 to be very easily turned back on.

Accordingly, one embodiment of the present disclosure may be advantageously applied, but is not limited to, low-noise amplifiers (or LNAs) in the receivers of wireless communications systems, such as cellular mobile telephones. Embodiments of the present disclosure provide a solution that allows the output current delivered by a transistor, for example the power supply current for an amplifier, to be brought to zero while at the same time benefiting from a fast restart of the amplifier operation after such a cutoff.

According to a first aspect, the present disclosure provides a method for controlling an output current delivered by a transistor in response to an input signal received on its control electrode. According to a general feature of this aspect of the present disclosure, since the the transistor is disposed inside a biasable semiconductor well of the SOI type, the value of the the output current is controlled by adjusting the value of the bias voltage of the well.

In other words, because of the use of a transistor formed inside a well of the SOI (Silicon-On-Insulator) type, the value of the output current of the transistor can be adjusted by varying the value of the bias voltage of the well. The reason for this is that the transistors fabricated within a semiconductor well of the SOI type comprise a well formed on a layer of insulator (for example SiO₂), which is itself formed on a substrate, for example of the p type, connected to ground, and accordingly can be biased using positive voltage values, in contrast to transistors of the standard type.

In one embodiment, by making the value of the bias voltage of the well vary, it could be possible to adjust the value of the output current from the transistor, as an alternative to varying the value of the control voltage of this transistor. The present disclosure could also provide an integrated circuit including at least one transistor that comprises an output electrode capable of delivering an output current in response to an input signal received on its control electrode.

In one embodiment, the transistor is disposed inside a biasable semiconductor well of the SOI type. The circuit could also include a control means capable of receiving a control signal and capable of adjusting the value of the bias voltage of the well as a function of the value of the control signal. The transistor is then able to generate an output current whose value depends on the value of the bias voltage of the well.

In one embodiment, the control means could include a limiting inverter capable of receiving the the control signal and capable of delivering to the well of the the transistor the corresponding value of the bias voltage. Furthermore, the circuit can also comprise at least one filter that comprises a terminal coupled to the output electrode of the the transistor. This filter can for example form part of an amplifier, for example a low-noise amplifier.

Accordingly, the present disclosure could provide a receiver belonging to a wireless communications system, comprising a circuit such as is defined hereinabove, and in particular forming a cellular mobile telephone.

It may be advantageous to set forth definitions of certain words and phrases used in this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method of controlling an output current of a transistor disposed inside a semiconductor well, the method comprising:
in response to an input signal received on a control electrode of the transistor, adjusting the value of a bias voltage of the semiconductor well.

2. The method according to claim 1, wherein the semiconductor well comprises an SOI type semiconductor well.

3. The method according to claim 1, wherein the step of adjusting comprises using a function of the value of the input signal.

4. The method according to claim 1, wherein the step of adjusting comprises receiving a control signal from a control circuit to adjust the value of the bias voltage of the semiconductor well as a function of the value of the control signal.

5. The method according to claim 4, wherein the control circuit comprises a limiting inverter to receive the control signal.

6. The method according to claim 5, wherein the limiting inverter delivers to the well of the transistor a corresponding value of the bias voltage.

7. The method according to claim 1, wherein an output electrode of the transistor is coupled to a terminal of an amplifier.

8. The method according to claim 1, wherein the transistor is part of a cellular mobile telephone.

9. An integrated circuit comprising:
a transistor disposed inside a semiconductor well, the transistor having an output electrode to deliver an output current in response to an input signal received on a control electrode of the transistor; and
a control circuit to receive a control signal and to adjust the value of the bias voltage of the semiconductor well as a function of the value of the control signal.

10. The integrated circuit according to claim 9, wherein the semiconductor well comprises an SOI type semiconductor well.

11. The integrated circuit according to claim 9, wherein the control circuit comprises a limiting inverter to receive the control signal.

12. The integrated circuit according to claim 11, wherein the limiting inverter delivers to the well of the transistor a corresponding value of the bias voltage.

13. The integrated circuit according to claim 9 further comprising:
an amplifier having a terminal coupled to the output electrode of the the transistor.

14. The integrated circuit according to claim 9 forming a circuit in a cellular mobile telephone.

15. For use in a wireless communication system, a receiver comprising:
a transistor disposed inside a semiconductor well, the transistor having an output electrode to deliver an output current in response to an input signal received on a control electrode of the transistor; and
a control circuit to receive a control signal and to adjust the value of the bias voltage of the semiconductor well as a function of the value of the control signal.

16. The receiver according to claim 15, wherein the semiconductor well comprises an SOI type semiconductor well.

17. The receiver according to claim 15, wherein the control circuit comprises a limiting inverter to receive the control signal.

18. The receiver according to claim 16, wherein the limiting inverter delivers to the well of the transistor a corresponding value of the bias voltage.

19. The receiver according to claim 15 further comprising:
an amplifier having a terminal coupled to the output electrode of the the transistor.

20. The receiver according to claim 15, forming a cellular mobile telephone.
